(19) United States
(12) Patent Application Publication
(10) Pub. No.: US 2011/0037119 A1
(43) Pub. Date: Feb. 17, 2011

(54) MEMORY

(75) Inventor: Weiran Kong, Shanghai (CN)

Correspondence Address: ROSENBERG, KLEIN & LEE, 3458 ELLICOTT CENTER DRIVE-SUITE 101, ELLICOTT CITY, MD, 21043, US

(73) Assignee: GRACE SEMICONDUCTOR MANUFACTURING CORP., Shanghai (CN)

(21) Appl. No.: 12/988,125

(22) PCT Filed: May 13, 2009
(86) PCT No.: PCT/CN2009/071775

§ 371 Date: Oct. 15, 2010

(30) Foreign Application Priority Data
Jan. 5, 2009 (CN) 200910044889.2

(51) Int. Cl. H01L 29/792

(52) U.S. Cl. 257/324; 257/E29.309

(57) ABSTRACT

A memory includes: a semiconductor substrate (1), a doped source area (2) and a doped drain area (3) set in the semiconductor substrate (1), and a channel area (4) set between said doped source area (2) and said doped drain area (3); a first insulating layer (5) located on the semiconductor substrate (1), a charge memory layer (6) composed of polysilicon located on said first insulating layer (5); an SiGe conducting layer (7) set in said charge memory layer (6).

### BACKGROUND OF THE INVENTION

1. Field of the Invention

The present invention relates to a semiconductor device, and in particular to a memory.

2. The Prior Arts

In general, a memory is utilized to store large amounts of data and information, and according to a recent survey/investigation, memory chips account for about 30% of the semiconductor business worldwide. In recent years, the rapid progress and development of science and technology and also the market demand have brought about various types of memories of increasing densities, such as Random Access Memory (RAM), Dynamic Random Access Memory (DRAM), Read Only Memory (ROM), Erasable Programmable Read Only Memory (EPROM), Flash Memory (FLASH). and Ferroelectric Random Access Memory (FRAM).

When utilizing a memory, users require the memory to have high storage capacity and low power consumption. In addition, high data storage reliability is also essential, since the capability to keep and hold the data stored is a critical and important parameter of reliability.

Presently, the tendency of memory technology development is toward increased integration and reduced element size. In order to increase integration and reduce unit area occupied in a same size chip area. much more storage units have to be produced, such that size of memory must be miniaturized continuously along with the progress and development of the technology. This is needed so that the amount of charges stored per data storage unit decreases along with the reduction of volume of data storage unit, such that in an entire data storage & holding period (in general at least 10 years) the amount of allowable lost charges also decreases. Therefore, the miniaturization of memory imposes a higher demand for better data storage & holding capability.

In this case, a flash memory is taken as an example for explanation. In this kind of memory, data storage is realized through storing charges in a floating gate. Though a floating gate and other conductive portions of a memory are separated by an insulating dielectric layer, due to the quantum tunneling effect, the charges in a floating gate always have the possibility of tunneling through the insulating dielectric layer. The tunneling probability will decrease exponentially along with the increase of thickness of the insulating dielectric layer. In order to ensure the data storage & holding capability of a memory, the insulating dielectric layer surrounding a floating gate must be assured of a specific physical thickness. This is especially true for the floating gate dielectric layer between a floating gate and a channel, since this part of gate dielectric layer is usually the thinnest of those surrounding a floating gate.

The above-mentioned phenomenon leads to a problem where the thickness of a gate dielectric layer of a floating gate can not be reduced proportionally. Thus this thicker floating gate dielectric layer will result in weaker control of the floating gate over the channel, thereby adversely affecting the performance of flash memory unit. Therefore, the conventional semiconductor memory technology has much room for improvement.

### SUMMARY OF THE INVENTION

In view of the problems and shortcomings of the prior art, the present invention provides a memory that is capable of raising the data storage and holding capability while reducing the size of the memory.

In order to achieve the above-mentioned objective of the present invention, the present invention provides a memory comprising a semiconductor substrate, a doped source area and a drain area, and a channel area between the source area and the drain area, all formed in the semiconductor substrate, a first insulation layer provided on the semiconductor substrate, a charge storage layer made of polysilicon and disposed on the first insulation layer, and an Si₁₋ₓGeₓ conductor layer is provided in the charge storage layer.

According to one aspect of the present invention, a second insulation layer is provided on the charge storage layer.

According to another aspect of the present invention, the second insulation layer is made of silicon oxide, silicon nitride, silicon nitrogen oxide, other dielectric layer of high dielectric constant, or any combinations thereof.

According to yet another aspect of the present invention, a control gate made of polysilicon or other conductive materials is provided on the second insulation layer.

According to still another aspect of the present invention, a control gate made of polysilicon or other conductive materials is provided on a side of the charge storage layer.

According to a further aspect of the present invention, the second insulation layer is used to separate the charge storage layer and the control gate.

According to another aspect of the present invention, the range of x for Si₁₋ₓGeₓ conductor layer is 0 to 1.

According to yet another aspect of the present invention, the charge storage layer is an n-type charge storage layer or a p-type charge storage layer.

According to a further aspect of the present invention, the channel area is an n-type channel area or a p-type channel area.

Moreover, in order to achieve the above-mentioned objectives of the present invention the present invention further provides another memory, comprising a semiconductor substrate, a doped source area and a drain area and a channel area between the source area and the drain area all formed in the semiconductor substrate, a first insulation layer provided on the semiconductor substrate, a charge storage layer made of polysilicon disposed on the first insulation layer, and an Si₁₋ₓGeₓ conductor layer is provided on the charge storage layer.

According to one aspect of the present invention, a second insulation layer is provided on the Si₁₋ₓGeₓ conductor layer.

According to another aspect of the present invention, a control gate made of polysilicon or other conductive materials is provided on the second insulation layer.

According to yet another aspect of the present invention, the second insulation layer is made of silicon oxide, silicon nitride, silicon nitrogen oxide, other dielectric layer of high dielectric constant, or any combination thereof.

According to another aspect of the present invention, control gates made of polysilicon or other conductive materials are provided on the sides of the charge storage layer and the Si₁₋ₓGeₓ conductor layer.

According to still another aspect of the present invention, the second insulation layer is used to separate the charge storage layer, the Si₁₋ₓGeₓ conductor layer, and the control gate.

According to another aspect of the present invention, the range of x for Si₁₋ₓGeₓ conductor layer is 0 to 1.

According to yet another aspect of the present invention, the charge storage layer is an n-type charge storage layer or a p-type charge storage layer.

According to a further aspect of the present invention, the channel area is an n-type channel area or a p-type channel area.

In the memory of the present invention, through the utilization of an Si₁₋ₓGeₓ conductor layer provided in an charge storage layer, charges stored in the charge storage layer are gathered and concentrated in the Si₁₋ₓGeₓ conductor layer. This significantly enlarges the distance to the substrate, increases the thickness of the insulating dielectric layer separating the charges, and reduces the possibility of charge leakage. As a result, the charge holding capability for the charges stored in the charge storage layer is increased, loss of data is prevented, and the life span of the charges stored is extended.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a schematic diagram of a memory structure according to the first embodiment of the present invention;

FIG. 2 is a schematic diagram of an energy band of a memory according to the first embodiment of the present invention;

FIG. 3 is a schematic diagram of the charge storage state of a memory according to the first embodiment of the present invention;

FIG. 4 is a schematic diagram of a memory structure according to the second embodiment of the present invention;

FIG. 5 is a schematic diagram of a memory structure according to the third embodiment of the present invention; and

FIG. 6 is a schematic diagram of a memory structure according to the fourth embodiment of the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

In the following descriptions embodiments are provided in order to present an clear and thorough understanding of the structure and application of the memory of the present invention.

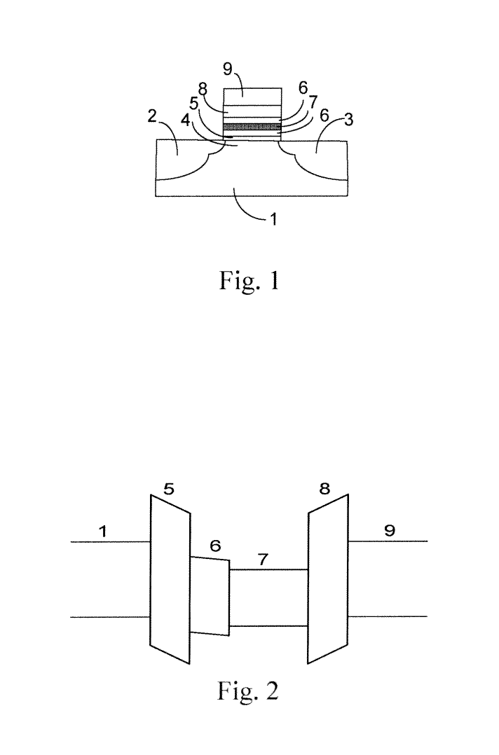

Refer to FIG. 1 for a schematic diagram of a memory structure according to the first embodiment of the present invention. As shown in FIG. 1, the non-volatile memory comprises a semiconductor substrate 1, a doped source area 2 and a drain area 3, and a channel area 4 between the source area and drain area, all formed in the semiconductor substrate 1. A first insulation layer 5 is provided on the semiconductor substrate 1. A charge storage layer 6 made of polysilicon is disposed on the first insulation layer 5. An Si₁₋ₓGeₓ conductor layer 7 is provided in the charge storage layer 6.

A second insulation layer 8 is provided on the charge storage layer 6. A control gate 9 made of polysilicon or other conductive material is provided on the second insulation layer 8. The second insulation layer 8 is made of silicon oxide, silicon nitride, silicon nitrogen oxide, other dielectric layer of high dielectric constant, or any combinations thereof, such as the dielectric structure of Oxide-Nitride-Oxide (ONO) or the dielectric structure of Oxide-Nitride (ON).

Refer to FIG. 2 for a schematic diagram of an energy band of a memory according to the first embodiment of the present invention. When a floating gate is provided with positive charges (mainly holes), its energy band is as shown in FIG. 2. Since the energy band gap of the Si₁₋ₓGeₓ conductor layer 7 is narrower than that of a charge storage layer 6 made of polysilicon, the valance band of the Si₁₋ₓGeₓ conductor layer 7 is higher than that of the polysilicon charge storage layer 6. Therefore, most of the free holes will be distributed inside the Si₁₋ₓGeₓ conductor layer 7, making them farther away from the interface of the polysilicon charge storage layer 6 and the first insulation layer 5. As a result, the probability of charges tunneling into the substrate 1 is reduced and the data holding capability is increased.

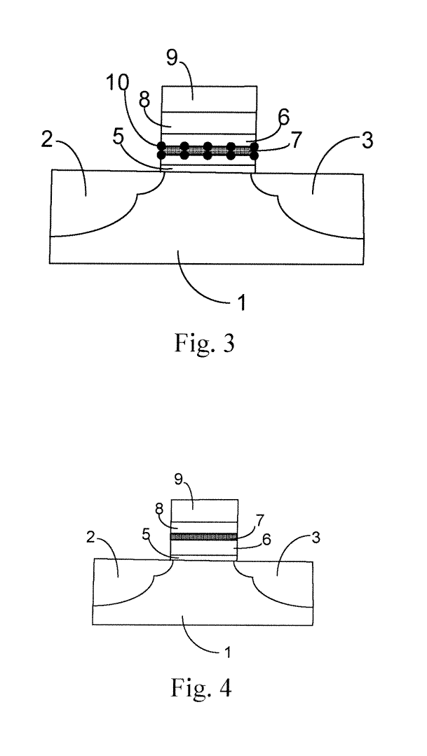

Refer to FIG. 3 for a schematic diagram of the charge storage state of a memory according to the first embodiment of the present invention. As shown in FIG. 3, the charge storage layer 6 is a p-type charge storage layer, the channel area 4 is a p-type channel area, and the range of x value for Si₁₋ₓGeₓ conductor layer 7 is 0-1. In the present embodiment, since the valance band of the Si₁₋ₓGeₓ is higher than that of silicon, holes 10 are gathered and concentrated at the interface of silicon and the Si₁₋ₓGeₓ, namely, the holes 10 are distributed at a contact interface between a charge storage layer 6 and an Si₁₋ₓGeₓ conductor layer 7 as shown in FIG. 3. Since the Si₁₋ₓGeₓ conductor layer 7 is in a charge storage layer 6, the holes 10 used for storing data are distributed in a contact interface between the charge storage layer 6 and the Si₁₋ₓGeₓ conductor layer 7. Compared with situations where charge distribution is in a contact interface between a charge storage layer 6 and a first insulation layer 5 without having an Si₁₋ₓGeₓ conductor layer 7, the structure of the present embodiment is capable of increasing the distance between charges and substrate 1. In this way, the thickness of the insulating dielectric layer used for separating charges is increased, the possibility of charge leakage is reduced, the charge holding capability for charges stored in a charge storage layer 6 is raised, thereby significantly avoiding data loss, and the life span of the charges stored is extended.

In an embodiment of the present invention the charge storage layer 6 is an n-type charge storage layer and the channel area is an n-type channel area and the structure is similarly formed to that of the p-type structure mentioned above. The difference is that electrons instead of holes are distributed in an interface between an Si₁₋ₓGeₓ conductor layer 7 and a charge storage layer 6.

Refer to FIG. 4 for a schematic diagram of a memory structure according to the second embodiment of the present invention. As shown in FIG. 4, the non-volatile memory comprises a semiconductor substrate 1, a doped source area 2 and a drain area 3, and a channel area 4 between the source area and the drain area, all formed in the semiconductor substrate 1. A first insulation layer 5 is provided on the semiconductor substrate 1 A charge storage layer 6 made of polysilicon is disposed on the first insulation layer 5. An Si₁₋ₓGeₓ conductor layer 7 is provided on the charge storage layer 6 and the range of x value for Si₁₋ₓGeₓ conductor layer 7 is 0-1.

A second insulation layer 8 is provided on the Si₁₋ₓGeₓ conductor layer 7 and a control gate 9 made of polysilicon or other conductive material is provided on the second insulation layer 8. The second insulation layer 8 is made of silicon oxide, silicon nitride, silicon nitrogen oxide, other dielectric layer of high dielectric constant, or any combinations thereof, such as the dielectric structure of Oxide-Nitride-Oxide (ONO) or the dielectric structure of Oxide-Nitride (ON).

In the embodiment shown in FIG. 4, the charge storage layer 6 is an n-type charge storage layer or a p-type charge storage layer, and the channel area is an n-type channel area or a p-type channel area. When electrons or holes are stored in the charge storage layer 6, the resulting effects are similar to those of the embodiment shown in FIG. 3. These electrons or holes are distributed in a contact interface between a charge storage layer 6 and an Si₁₋ₓGeₓ conductor layer 7, and in a contact interface between an Si₁₋ₓGeₓ conductor layer 7 and a second insulation layer 8.

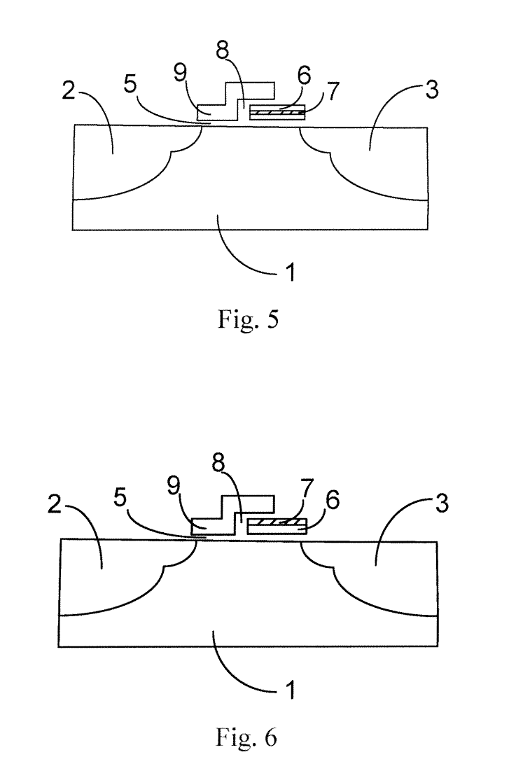

Refer to FIG. 5 for a schematic diagram of a memory structure according to the third embodiment of the present invention. As shown in FIG. 5, anon-volatile memory comprises a semiconductor substrate 1, a doped source area 2 and a drain area 3, and a channel area 4 between the source area 2 and the drain area 3, all formed in the semiconductor substrate 1. A first insulation layer 5 is provided on the semiconductor substrate 1 and a charge storage layer 6 made of polysilicon is disposed on the first insulation layer 5. An Si₁₋ₓGeₓ conductor layer 7 is provided in the charge storage layer 6, and the range of x value for the Si₁₋ₓGeₓ conductor layer 7 is 0-1.

On a side of the charge storage layer 6 a control gate 9 made of polysilicon or other conductive materials is provided. The second insulation layer 8 is used to separate the charge storage layer 6 and the control gate 9. The second insulation layer 8 is made of silicon oxide, silicon nitride, silicon nitrogen oxide, other dielectric layer of high dielectric constant, or any combinations thereof, such as the dielectric structure of Oxide-Nitride-Oxide (ONO) or the dielectric structure of Oxide-Nitride (ON).

In embodiments of the present invention, the charge storage layer 6 is an n-type charge storage layer or a p-type charge storage layer, and the channel area is an n-type channel area or a p-type channel area, such that when electrons or holes are stored in the charge storage layer 6, the resulting effects are similar to those of embodiments previously described.

Refer to FIG. 6 Dora schematic diagram of a memory structure according to the fourth embodiment of the present invention. As shown in FIG. 6 the non-volatile memory comprises a semiconductor substrate 1, a doped source area 2 and a drain area 3, and a channel area 4 between the source area 2 and the drain area 3, all formed in the semiconductor substrate 1. A first insulation layer 5 is provided on the semiconductor substrate 1 and a charge storage layer 6 made of polysilicon is disposed on the first insulation layer 5. An Si₁₋ₓGeₓ conductor layer 7 is provided on the charge storage layer 6 and the range of x value for the Si₁₋ₓGeₓ conductor layer 7 is 0-1.

On the side of the charge storage layer 6 a control gate 9 made of polysilicon or other conductive materials is provided. The second insulation layer 8 is used to separate the charge storage layer 6, the Si₁₋ₓGeₓ conductor layer 7 thereon, and the control gate 9. The second insulation layer 8 is made of silicon oxide, silicon nitride, silicon nitrogen oxide, other dielectric layer of high dielectric constant, or any combinations thereof, such as the dielectric structure of Oxide-Nitride-Oxide (ONO) or the dielectric structure of Oxide-Nitride (ON).

In the structure mentioned above, the charge storage layer 6 is an n-type charge storage layer or a p-type charge storage layer, and the channel area is an n-type channel area or a p-type channel area, such that when electrons or holes are stored in the charge storage layer 6 the resulting effects are similar to the second embodiment previously described.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A memory, comprising:
a semiconductor substrate;
a doped source area and a drain area, and a channel area between said source area and said drain area, all formed in said semiconductor substrate;
a first insulation layer provided on said semiconductor substrate; and
a charge storage layer made of polysilicon disposed on said first insulation layer,
wherein an Si₁₋ₓGeₓ conductor layer is provided in said charge storage layer.

2. The memory as claimed in claim 1, wherein a second insulation layer is disposed on said charge storage layer.

3. The memory as claimed in claim 2, wherein said second insulation layer is made of silicon oxide, silicon nitride, silicon nitrogen oxide, other dielectric layers of high dielectric constants, or any combinations thereof.

4. The memory as claimed in claim 2, wherein a control gate made of polysilicon or other conductive materials is provided on said second insulation layer.

5. The memory as claimed in claim I, wherein said control gate made of polysilicon or other conductive materials is provided on a side of said charge storage layer.

6. The memory as claimed in claim 5, wherein said second insulation layer is used to separate said charge storage layer and said control gate.

7. The memory as claimed in claim 1, wherein a range of x value for said Si₁₋ₓGeₓ conductor layer is 0 to 1.

8. The memory as claimed in claim 1, wherein said charge storage layer is an n-type charge storage layer or a p-type charge storage layer.

9. The memory as claimed in claim 1, wherein said channel area is an n-type channel area or a p-type channel area.

10. A memory, comprising:
a semiconductor substrate;
a doped source area and a drain area, and a channel area between said source area and said drain area, all formed in said semiconductor substrate;
a first insulation layer provided on said semiconductor substrate; and
a charge storage layer made of polysilicon disposed on said first insulation layer
wherein, an Si₁₋ₓGeₓ conductor layer is provided on said charge storage layer.

11. The memory as claimed in claim 10, wherein a second insulation layer is disposed on said Si₁₋ₓGeₓ conductor layer.

12. The memory as claimed in claim 11, wherein a control gate made of polysilicon or other conductive materials is provided on said second insulation layer.

13. The memory as claimed in claim 11 or 12, wherein said second insulation layer is made of silicon oxide, silicon nitride, silicon nitrogen oxide, other dielectric layers of high dielectric constants, or any combinations thereof.

14. The memory as claimed in claim 10, wherein on sides of said charge storage layer and said Si₁₋ₓGeₓ conductor layer said control gate made of polysilicon or other conductive materials is provided.

15. The memory as claimed in claim 14, wherein said second insulation layer is used to separate said charge storage layer, said Si₁₋ₓGeₓ conductor layer, and said control gate.

16. The memory as claimed in claim 10, wherein a range of x value for said Si₁₋ₓGeₓ conductor layer is 0 to 1.

17. The memory as claimed in claim 10, wherein said charge storage layer is an n-type charge storage layer or a p-type charge storage layer.

18. The memory as claimed in claim 10, wherein said channel area is an n-type channel area or a p-type channel area.
